(19) United States
(12) Patent Application Publication
(10) Pub. No.: US 2009/0032958 A1
(43) Pub. Date: Feb. 5, 2009

(54) Intermetallic conductors

(75) Inventor: Paul A. Farrar, Okatie, SC (US)

Correspondence Address: MUETING, RAASCH & GEBHARDT, P.A., P.O. BOX 581336, MINNEAPOLIS, MN, 55458-1336, US

(73) Assignee: MICRON TECHNOLOGY, INC., Boise, ID (US)

(21) Appl. No.: 11/888,946

(22) Filed: Aug. 3, 2007

(51) Int. Cl. H01L 23/52; H01L 21/4763

(52) U.S. Cl. 257/771; 438/642; 438/652; 257/E23.141; 257/E21.495

(57) ABSTRACT

Intermetallic conductive materials are used to form interconnects in an integrated circuit. In some cases, the intermetallic conductive material may be an intermetallic alloy of aluminum.

### BACKGROUND

As the minimum feature size achievable in semiconductor manufacturing decreases, the number of devices that can be incorporated into a given area increases as a second power function, and the number of wiring connections can increase at least as rapidly. In order to accommodate the increased numbers of connections, the wiring may be made increasingly fine and/or the space between adjacent lines may be reduced.

Fine wire interconnects are susceptible to failure as a result of phenomena such as mechanical stress and electromigration. Electromigration is a phenomenon in which ions of a metal conductor migrate, thereby changing the current flow character of the conductor, resulting, for example, in a short circuit or open circuit.

The increasing number of wiring connections in a given area has led to at least two different developments. One development is the use of a local wiring level to connect adjacent and nearly adjacent devices. The second development is the use of three dimensional solutions in which a recess (e.g., a hole or via) is made (e.g., by etching) through a dielectric covering of one level, thereby exposing a metal contact of a device on a lower level. The recess is filled with a conductive material and additional structure (e.g., a device, interconnect, etc.) can be applied over the filled recess so that the conductive material in the recess provides an electrical connection between the first and second levels.

Many different materials have been employed as metal interconnects. For example, aluminum possesses high conductivity and is compatible with many fabrication methods. Aluminum is, however, susceptible to electromigration. Copper also possesses high conductivity. However, copper is not very compatible with certain fabrication techniques (e.g., photoresist masking and plasma etching do not work well to pattern copper) and possesses a high diffusion coefficient in silicon. Tungsten has a high electromigration resistance and doesn't readily diffuse into silicon. However, tungsten possesses relatively low conductivity and does not adhere well to silicon. Other potential elements such as molybdenum and tantalum present other problems. Molybdenum, for example, forms an oxide that is easily removed, thereby enabling it to react with the environment.

One way to reduce the limitations (e.g., electromigration, diffusion, adherence) of the listed materials for use as metal interconnects includes forming a layer of functional material over at least part of the interconnect. Depending upon the composition of the layer of functional material, it can act as a barrier layer to reduce electromigration and/or diffusion, act as a liner to increase adherence of the conductor to a substrate, and/or protect the conductor from the environment. Of course, the presence of such layers increases the size of the interconnect, which negates to some extent the benefit of using fine wire interconnects, and adds manufacturing complexity.

### BRIEF DESCRIPTION OF THE DRAWING

FIG. 1A shows a cross-sectional view of a first metal layer deposited on a surface of a substrate assembly.

FIG. 1B shows a cross-sectional view of a second metal layer deposited on the first metal layer of the substrate assembly shown in FIG. 1A.

FIG. 1C shows a cross-sectional view of an optional third metal layer deposited on the second metal layer of the substrate assembly shown in FIG. 1B.

FIG. 2 shows a cross-sectional view of an intermetallic conductive layer formed on a surface of the substrate assembly shown in FIGS. 1A-1C.

FIG. 3 shows a cross-sectional view of a metal mixture layer deposited on a surface of a substrate assembly.

### DETAILED DESCRIPTION OF ILLUSTRATIVE EMBODIMENTS

It has been found that certain intermetallic compounds can be used as the conductive material in a conductive line of an integrated circuit (e.g., memory devices, processors, etc.) such as those used, for example, in consumer products and systems (e.g., cameras, phones, wireless devices, displays, chip sets, set top boxes, games, vehicles, etc.). Use of an intermetallic conductive material in a conductive line can limit electromigration and diffusion of the conductor into, for example, a semiconductor substrate made of silicon better than materials (e.g., gold, copper) that require a barrier layer. A conductive line that includes an intermetallic conductive material also can adhere to a semiconductor substrate better than materials (e.g., tungsten) that require a liner. A conductive line that includes an intermetallic conductive material also can be more environmentally stable than materials (e.g., molybdenum, copper) that require a liner to protect the conductor. Consequently, a conductive line that includes an intermetallic conductive material can be particularly well suited for use, for example, as a fine wire interconnect.

In one embodiment, the invention provides an electrically conductive line that includes a continuous length of an intermetallic conductive material having a longitudinal dimension defined by a first end connectable to a first component of an integrated circuit and a second end connectable to second component of an integrated circuit.

Conductive lines including an intermetallic conductive material may be used to construct first levels of interconnect (e.g., local interconnects), horizontal interconnects, such as those between interlevel dielectrics, and/or vertical connections between layers or different levels (e.g., contacts, vias, etc.). As used herein, directions (e.g., up, down, etc.) and orientations (e.g., horizontal, vertical, etc.) are interpreted with respect to the base semiconductor layer of the substrate assembly, regardless of the orientation of the substrate assembly in three-dimensional space. Further, the terms vertical and horizontal as used herein with respect to an interconnect does not necessarily mean that the interconnect lies along a single plane that is horizontal or vertical relative to the base semiconductor layer, but rather that the interconnect extends in the same direction (e.g., along a level) as the base semiconductor layer when it is horizontal (but not necessarily parallel) and extends between one or more layers or leads formed on a base semiconductor layer when it is vertical. For example, a horizontal interconnect may be formed over irregular structures along a level such that the horizontal interconnect does not lie along a single plane. Thus, a conductive line including an intermetallic conductive material may form a local interconnect, interconnects between interlevel dielectrics, vias, contacts, etc.

“Semiconductor substrate” or “substrate assembly” as used herein refer to a semiconductor substrate such as a base semiconductor layer or a semiconductor substrate having one or more layers, structures, or regions formed thereon. A base semiconductor layer is typically the lowest layer of silicon material on a wafer or a silicon layer deposited on another material, such as, for example, silicon on sapphire. When reference is made to a semiconductor substrate or substrate assembly, various process steps may have been previously used to form or define one or more integrated circuit components. As used herein, the term “integrated circuit component” refers generally to a region, junction, structure, feature, and/or opening such as, for example, a contact (including a first level contact), an electrode, a source, a drain, a transistor, an active area, an implanted region, a via, an interconnect including a local interconnect or an interconnect formed between interlevel dielectric layers, a contact opening, a high aspect ratio opening, a capacitor plate, a barrier for a capacitor, etc.

A wide variety of materials may be used to form the substrate assembly such as, for example, silicon oxide, borophosphosilicate glass (BPSG), silicon such as, e.g., conductively doped polysilicon, monocrystalline silicon, etc. (for this disclosure, appropriate forms of silicon are simply referred to as “silicon”, for example in the form of a silicon wafer), tetraethylorthosilicate (TEOS) oxide, spin on glass (i.e., a thin layer of SiO₂, optionally doped, deposited by a spin on process), TiN, TaN, W, Ru, Al, Cu, noble metals, etc. A substrate assembly may also contain a layer that includes platinum, iridium, iridium oxide, rhodium, ruthenium, ruthenium oxide, strontium ruthenate, lanthanum nickelate, titanium nitride, tantalum nitride, tantalum-silicon-nitride, silicon dioxide, aluminum, gallium arsenide, glass, etc., and other existing or to-be-developed materials used in constructions, such as, for example, dynamic random access memory (DRAM) devices, static random access memory (SRAM) devices, and ferroelectric memory (FERAM) devices, for example. The layers of a substrate assembly can be formed directly on a surface of the base semiconductor layer, or they can be formed on any of a variety of the layers (i.e., surfaces) as in a patterned wafer, for example.

Intermetallic compounds are a subset of metal alloys. An intermetallic compound is a material composed of two or more types of metal atoms in a defined composition, which exists as a homogeneous, composite substance that forms a distinct crystalline species separated by phase boundaries from its metallic components and/or mixed crystals of these components. Thus, intermetallic compounds are distinguished from other metal alloys that exist as a mixture of metallic phases.

Moreover, intermetallic compounds typically exist over a relatively defined compositional range that generally corresponds to the ratio of atoms in the intermetallic compound. Thus, for example, the intermetallic compound TiAl₃ can be formed by providing an approximately 3:1 atomic ratio of aluminum to titanium—i.e., a composition that is from about 60% to about 63% aluminum by weight—and then heat treating the aluminum and titanium to form the intermetallic compound. Similarly, the intermetallic compound Al₂Cu can be formed by providing an approximately 2:1 atomic ration of aluminum to copper—i.e., a composition that is from about 45% to about 47% aluminum by weight—and then heat treating the aluminum and copper to form the intermetallic compound. In some embodiments, the intermetallic compound can include two elements in an atomic ratio of about 1:1. In other embodiments, the intermetallic compound can include two elements in an atomic ratio of at least 2:1, such as, for example, an atomic ratio of 2:1, 3:2, 5:3, 3:1, 4:1, or 5:1. An intermetallic compound may have an atomic ratio of up to about 20:1, such as, for example, up to 10:1, up to 5:1, or up to 4:1.

Intermetallic compounds have been employed as, for example, barrier layers and/or adhesive liner layers for conductive metal lines. “Layer,” as used herein, refers to any layer that can be formed on a substrate or substrate assembly from one or more precursors and/or reactants according to a formation process (e.g., a process such as sputtering). The term “layer” is meant to include layers specific to the semiconductor industry, such as, but clearly not limited to, a barrier layer, dielectric layer (e.g., a layer having a high dielectric constant), and conductive layer

When intermetallic compounds have been used to form a functional layer on a conventional conductive line, the material of the conductive line used in combination with the functional layer (e.g., an underlying conductive metal layer) is the primary conductive path. To the extent that an intermetallic layer is coextensive with, and continuous along, the length of, for example, an underlying conductive metal layer, the intermetallic layer may provide a secondary conductive path. That is, the resistivity of the intermetallic layer is greater than the resistivity of the underlying conductive metal layer and, consequently, the conductivity of the underlying conductive metal layer is greater than the intermetallic layer.

In contrast, a conductive line that includes a length of continuous intermetallic material as described herein is employed as the primary route of electrical conductance. The conductive line may have a layer of non-intermetallic functional material disposed on some portion, even perhaps all, of its length. However, among materials in any layers that are coextensive with the intermetallic material in the conductive line connecting two integrated circuit components, the intermetallic material is the primary conductive path in the conductive line. In a construction in which the conductive line includes a length of intermetallic conductive material and a layer of non-intermetallic material that is co-extensive with, and continuous along, the length of the intermetallic conductive material, the intermetallic conductive material possesses less resistivity than the layer of non-intermetallic material.

The conductive line possesses a longitudinal dimension defined by two ends, each of which is connectable to an integrated circuit component. In embodiments in which the integrated circuit components are at the same level of integrated circuit structure, the conductive line can form a horizontal connection between the components. In embodiments in which the integrated circuit components are on different levels of integrated circuit structure, the intermetallic conductive line can form a vertical connection between the components.

The conductive line includes a length of intermetallic compound that is continuous between the two ends that define the longitudinal dimension. That is, the length of intermetallic compound is conductively continuous, able to provide uninterrupted current flow from one end of the conductive line to the other.

In some embodiments, the intermetallic compound can be substantially uniform throughout the length of the intermetallic conductive line. In other words, the majority of the intermetallic conductive line can be composed of a relatively uniform intermetallic alloy. In such embodiments, some non-uniformity may be expected within the intermetallic conductive line due to certain limitations of fabrication. For example, in forming an intermetallic compound of metal A and metal B, one expects that in addition to the intermetallic compound AₓB_{y}, some excess of either metal A and/or metal B will remain. Also, a plurality of metals may be capable of forming a series of intermetallic compounds, some with very narrow compositional ranges while other intermetallic compounds exist over a significant range of compositions. For example, titanium and aluminum can form intermetallic compounds including, e.g., TiAl₃, γ and δ. As used herein, the term “substantially uniform” allows for the presence of alternative members of a series of intermetallic compounds and/or inclusion of inconsequential amounts of excess metal. Where the range of solubility of the desired intermetallic compound is greater than the degree of control of the deposition process of the constituent elements, then the compound could be used in its pure state. Other extraneous impurity elements may be kept to as low a composition as is practicable such as, for example, generally less than about one percent.

In some embodiments, the intermetallic conductive line includes two or more intermetallic compounds of a series of intermetallic compounds. The particular species of intermetallic compound within a series that predominates can be controlled to some extent by the atomic ratio of the metals used to form the intermetallic compound. For example, the intermetallic compound TiAl₃ is expected to predominate if the compound is formed from a composition having about a 3:1 atomic ratio of aluminum to titanium—i.e., a composition that is from about 60% to 62% aluminum by weight. In some of these embodiments, one intermetallic compound is at least 95% of the intermetallic compounds present. In other embodiments, one intermetallic compound is at least 99% of the intermetallic compounds present. In other embodiments, one intermetallic compound is at least 99.9% of the intermetallic compounds present. In still other embodiments, one intermetallic compound is at least 99.99% of the intermetallic compounds present.

The term “substantially uniform” is used to describe the composition of the intermetallic conductive material—i.e., the intermetallic material that is forming the primary route of conductance along the length of the line—but not necessarily the conductive line as a whole. The conductive line may include additional structures and/or features that need not be intermetallic. For example, functional layers that may be made from materials that are not “substantially uniform” intermetallic materials may be coated on or affixed to the intermetallic conductive material, or otherwise incorporated into at least a portion of the conductive line. Even if such structures or features locally modify the chemistry of the underlying intermetallic conductive material, such localized modifications are contemplated within the scope of substantially uniform intermetallic material.

The intermetallic compound selected for use as the intermetallic conductive material should be stable over the range of temperatures the device will be exposed to during both manufacture and use. As used herein, “stable” means that the compound, after formation, should not decompose into either a different compound or an element and a compound during subsequent processing or use conditions. In some embodiments, the intermetallic compound is stable at temperatures up to 750° C. In other embodiments, the intermetallic compound is stable at temperatures up to 550° C. In still other embodiments, the intermetallic compound is stable at temperatures up to 350° C.

The intermetallic compound should have sufficient conductivity—i.e., sufficiently low resistivity—to perform as desired. The direct current resistivity of a structure is generally proportional to its length. Therefore, intermetallic compounds having a relatively greater specific electrical resistance may be suitable for connections over short distances. For example, intermetallic compounds suitable for use as the intermetallic conductive material can have a specific electrical resistance of up to 1000 μΩcm. In some embodiments, a suitable intermetallic compound can have a specific electrical resistance of up to 100 μΩcm. In still other embodiments, a suitable intermetallic compound can have a specific electrical resistance of up to 10-10 μΩcm.

When the connection distances are short, the resistance of the intermetallic conductive line can be inconsequential compared to the resistance offered by junctions and/or transistors. As such, intermetallic compounds may be suitable for use in shorter connections. The practical limits are at least partially dependent upon the specific process being used and the specific design being produced. As minimum photolithographic dimensions achievable in designs have shrunk from one micron to 0.1 micron, the vertical dimensions (i.e., film thickness) have not always shrunk at the same rate. Thus, the maximum number of minimum photo dimensions equal to the maximum desirable length of a conductor achievable, at the minimum photo dimensions, can very with the thickness of the conductor used along with the specific resistance of the conductor material. Therefore, any design limits are a function of many factors including, for example, material properties, minimum photo dimensions, alternate wiring levels available, and specific circuit design.

In some embodiments, a conductive line that includes an intermetallic conductive material may have a length of up to 250 minimum photo dimensions. In other embodiments, a conductive line that includes an intermetallic conductive material may have a length of up to 100 minimum photo dimensions. In still other embodiments, a conductive line that includes an intermetallic conductive material may have a length of up to 50 minimum photo dimensions.

The intermetallic material may include any intermetallic compound that meets fabrication and performance requirements for a particular application. In many embodiments, the intermetallic compound can include atoms of aluminum, gold, cobalt, copper, chromium, iron, niobium, hafnium, palladium, platinum, tantalum, titanium, vanadium, zirconium, or any combination of two or more of the foregoing. Intermetallic aluminum alloys with hafnium, palladium, platinum, tantalum, titanium, vanadium, or zirconium exist as series of multiple compounds.

In certain embodiments, the intermetallic compound can be an intermetallic alloy of aluminum such as, for example, Al₂Au, Al₂Cu, AlCu, FeAl₃, and Al₃Nb. In one particular embodiment, the intermetallic compound can be Al₂Cu. Al₂Cu has low to negligible solubility for silicon, possesses reasonable conductivity, is stable to temperatures above 500° C., and may be formed from a composition that contains from about 31.9% to about 33% copper by weight. Moreover, the partition function of copper between Al₂Cu and silicon, or between a solid solution of copper in aluminum and silicon, is such that copper tends not to diffuse into the silicon and, therefore, the use of Al₂Cu as an intermetallic conductive material is unlikely to result in junction poisoning.

In other embodiments, the invention provides methods of forming an intermetallic conductive line that includes an intermetallic compound of two or more metals, e.g., a first metal and a second metal. Generally, the method includes providing a substrate or substrate assembly having a surface, depositing layers of the metals on at least a portion of the surface, and heating the layers for a sufficient time at a sufficient temperature to form a layer of intermetallic compound including the deposited metals.

In some embodiments, the method can include etching a pattern of openings such as, for example, trenches, into the substrate surface. In other embodiments, the surface on which the metals are deposited can be the surface of a recess e.g., a hole, a contact opening, or a via-formed through the surface of the substrate assembly.

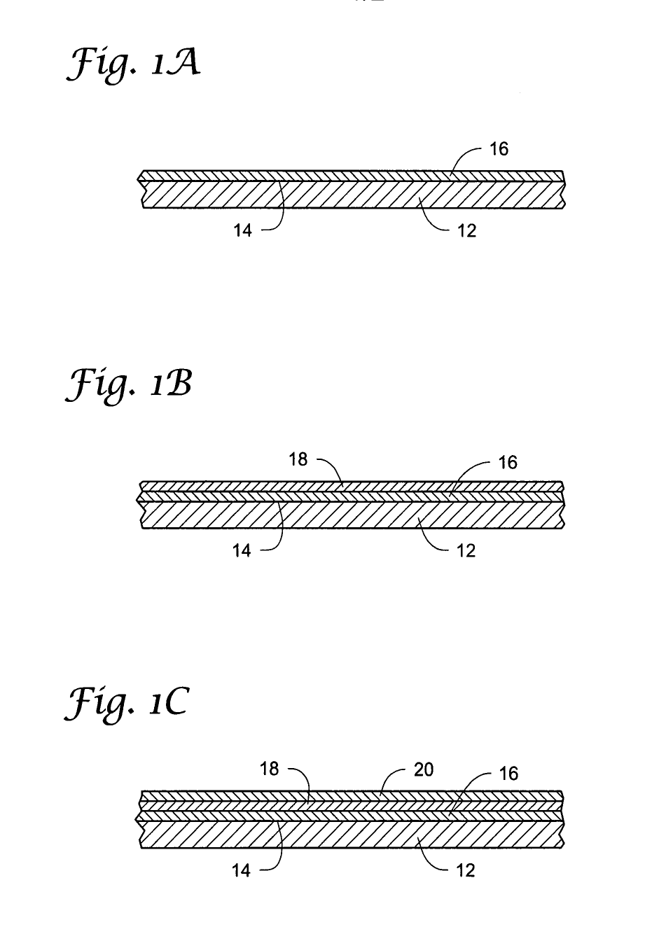

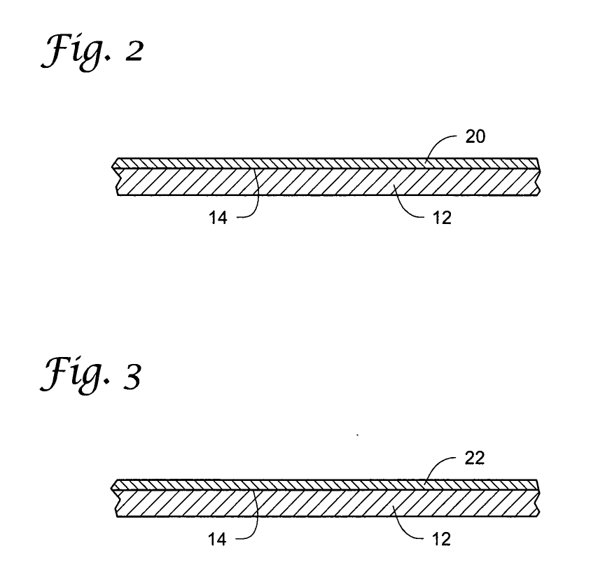

FIG. 1A shows a substrate assembly 12 having a surface 14, e.g., a surface defining a trench or contact opening, a surface of a dielectric material, etc. A first metal may be deposited in a first layer 16 on the surface 14. FIG. 1B shows a second metal deposited as a second layer 18 on at least a portion of the first metal layer 16. If the intermetallic compound includes more than two metals, one or more optional layers 20 may be deposited, as shown in FIG. 1C. After the metal layers have been deposited, the layers are heated for a sufficient time at a sufficient temperature for the metal layers to form an intermetallic conductive material 20, shown in FIG. 2.

Referring again to FIG. 1C, any suitable number of optional metal layers 20 may be deposited. Optional additional layers 20 may provide one or more additional metal or metals necessary to form the desired intermetallic conductive material. In other cases, the optional additional layers 20 may provide additional quantities of metals already deposited in previous layers in order, for example, to provide the desired stoichiometry of metal atoms to form a particular intermetallic species of a series.

FIG. 3 shows an embodiment in which a single layer 22 that includes a mixture of the metals needed to form the desired intermetallic conductive material is deposited as a mixture on at least a portion of the surface 14 of a substrate assembly 12.

In embodiments in which the intermetallic material is formed by alternate layer deposition, the thickness of each layer can be managed so that the equilibrium compound composition can be achieved with modest time temperature exposure such as, for example, less than 450° for less than three hours.

Whether formed as separate layers (e.g., and then thermally treated or formed as a mixture, the metals may be deposited by any suitable technique including but not limited to atomic layer deposition (ALD), chemical vapor deposition (CVD), electroplating, electroless plating, evaporation, and sputtering.

ALD and CVD are two vapor deposition processes often employed to form thin, continuous, uniform, metal-containing layers onto substrates such as, for example, semiconductor substrates or dielectric layers in a semiconductor device. ALD permits deposition of a single atomic layer of the material being formed. Deposition of metal by ALD can minimize the time temperature exposure necessary to form the intermetallic material.

Generally, using either vapor deposition process, a precursor composition including one or more metals of the intermetallic material is vaporized in a deposition chamber and optionally combined with one or more reaction gases and directed to and/or contacted with the substrate to form a metal layer on the substrate. It will be readily apparent to one skilled in the art that the vapor deposition process may be enhanced by employing various related techniques such as plasma assistance, photo assistance, laser assistance, as well as other techniques.

Generally, ALD involves a series of deposition cycles conducted in a process chamber (i.e., a deposition chamber). Typically, during each cycle, metal atoms are chemisorbed to a deposition surface (e.g., a substrate assembly surface or a previously deposited underlying surface such as material from a previous ALD cycle), forming a monolayer of atoms. Thereafter, if desired, one or more subsequent layers of metal atoms may be deposited by repeating the deposition process until the composition range for the desired intermetallic compound is attained.

ALD, as used herein, is also meant to include processes designated by related terms such as, “chemical vapor atomic layer deposition,” “atomic layer epitaxy” (ALE) (see U.S. Pat. No. 5,256,244 to Ackerman), molecular beam epitaxy (MBE), gas source MBE, or organometallic MBE, and chemical beam epitaxy when performed with alternating pulses of precursor composition(s), reactive gas, and purge (e.g., inert carrier) gas.

A typical CVD process may be carried out in a chemical vapor deposition reactor, such as a deposition chamber available under the trade designation of 7000 from Genus, Inc. (Sunnyvale, Calif.), a deposition chamber available under the trade designation of 5000 from Applied Materials, Inc. (Santa Clara, Calif.), or a deposition chamber available under the trade designation of Prism from Novelus, Inc. (San Jose, Calif.). However, any deposition chamber suitable for performing CVD may be used.

In one embodiment of forming an Al₂Cu material, a silicon dioxide (SiO₂) substrate (e.g., an insulator the same thickness as the desired conductive metallurgy) is etched to form a pattern of trenches using standard photolithographic techniques. A hard mask (e.g., Si₃N₄) is used in the photolithography technique to define the pattern and is left in place after removal of the photoresist layer.

A 50 Å layer of aluminum is deposited by CVD. A 100 Å layer of copper is deposited on the aluminum layer using electroless plating. A 2531 Å layer of aluminum is deposited on the layer of copper by CVD. Finally, a 2289 Å layer of copper is deposited on the previous layer of aluminum.

The layered substrate is heated at 350° C. for one approximately one hour to form the Al₂Cu. Chemical-mechanical planarization (CMP) is used to remove the Al₂Cu from areas outside of the etched trenches using the hard mask (e.g., Si₃N₄) as a stop layer. The Si₃N₄ would then be polished away such that the oxide was exposed in high spots and left in any low spots.

When vertical connections are to be made, a dual damascene process could be used. If through wafer connections are desired, then the through hole could be etched and either an insulator film could be formed by oxidizing the hole or an insulator could be deposited in the hole and a smaller hole etched through the insulator. Alternating layers of the elements that form the intermetallic conductive material could be deposited so that the intermetallic conductive material can be formed by heat treatment. Alternatively, the elements that form the intermetallic conductive material can be co-deposited and then heat treated to form the intermetallic material.

In some embodiments, the invention provides an integrated circuit that includes at least one conductive line that includes a length of the continuous intermetallic conductive material described above. As described above, the conductive line may connect two or more components of an integrated circuit.

In still other embodiments, the invention provides a semiconductor device that includes a semiconductor substrate assembly including a plurality of integrated circuit components and at least one conductive line that includes a length of the continuous intermetallic conductive material described herein.

The complete disclosures of the patents, patent documents, and publications cited herein are incorporated by reference in their entirety as if each were individually incorporated. Various modifications and alterations to the embodiments described herein will become apparent to those skilled in the art without departing from the scope of the present disclosure. It should be understood that this disclosure is not intended to be unduly limited by the illustrative embodiments set forth herein and that such embodiments are presented by way of example only with the scope of the disclosure intended to be limited only by the claims set forth herein as follows. As used herein, the term “comprising,” which is synonymous with “including” or “containing,” is inclusive, open-ended, and does not exclude additional unrecited elements or method steps.

What is claimed is:

1. An electrically conductive line comprising:
a length of continuous intermetallic conductive material having a longitudinal dimension defined by a first end connectable to a first component of an integrated circuit and a second end connectable to second component of an integrated circuit.

2. The electrically conductive line of claim 1 wherein intermetallic conductive material provides a primary route of electrical conductance.

3. The electrically conductive line of claim 1 wherein the intermetallic conductive material comprises an alloy of aluminum.

4. The electrically conductive line of claim 3 wherein the alloy of aluminum comprises gold, cobalt, copper, chromium, iron, niobium, hafnium, palladium, platinum, tantalum, titanium, vanadium, zirconium, or a combination thereof.

5. The electrically conductive line of claim 3 wherein the alloy of aluminum comprises gold, cobalt, copper, chromium, iron, niobium, or a combination thereof.

6. The electrically conductive line of claim 3 wherein the alloy of aluminum comprises copper.

7. The electrically conductive line of claim 3 wherein the alloy of aluminum has an atomic composition of Al₂Cu.

8. The electrically conductive line of claim 1 wherein the length of continuous, intermetallic conductive material is substantially uniform.

9. An integrated circuit comprising:
a first component of an integrated circuit;
a second component of an integrated circuit; and
at least one conductive line that comprises a length of continuous intermetallic conductive material having a longitudinal dimension defined by a first end connected to the first component of the integrated circuit and a second end connected to the second component of the integrated circuit, wherein the intermetallic conductive material provides a primary conductive path between the first end and the second end.

10. The integrated circuit of claim 9 wherein the first component and the second component are parts of an active device of the integrated circuit and the conductive line is a local interconnect therebetween.

11. A semiconductor device comprising:
a substrate assembly comprising a plurality of integrated circuit components; and
at least one conductive line comprising a length of continuous intermetallic conductive material having a longitudinal dimension defined by a first end connected to a first integrated circuit and a second end connected to second integrated circuit component, wherein the intermetallic conductive material provides a primary conductive path between the first end and the second end.

12. A method of forming an intermetallic conductive line comprising:
providing a substrate assembly having a surface;
depositing at least one layer comprising a first metal on at least a portion of the surface;
depositing at least one layer comprising a second metal on at least a portion of the layer of the first metal; and
thermally treating the layer comprising the first metal and the layer comprising the second metal to form a layer of intermetallic compound comprising the first metal and the second metal.

13. The method of claim 12 further comprising etching a pattern of one or more openings into the surface, wherein the at least one metal layer is deposited in at least a portion of the pattern.

14. The method of claim 12 further comprising:
depositing a second layer of the first metal on at least a portion of the layer of second metal; and
depositing a second layer of the second metal on at least a portion of the second layer of the first metal.

15. The method of claim 12 wherein the first metal or the second metal is aluminum.

16. The method of claim 12 wherein the first metal or the second metal is copper.

17. The method of claim 12 further comprising depositing at least one layer comprising a third metal on at least a portion of the layer of the first metal or on at least a portion of the layer of the second metal, and wherein thermally treating the layer comprises forming a layer of intermetallic compound comprising the first metal, the second metal, and the third metal.

18. A method of forming an intermetallic conductive line comprising:
providing an substrate assembly having a surface;
depositing a mixture of at least a first metal and a second metal on at least a portion of the substrate assembly, wherein the mixture comprises the first metal and the second metal in stoichiometric proportions effective for forming an intermetallic compound; and
thermally treating the mixture to form a layer of the intermetallic compound comprising the first metal and the second metal.

19. The method of claim 18 further comprising etching a predetermined pattern of one or more openings into the surface, wherein the mixture is deposited in at least a portion of the pattern.

20. The method of claim 18 wherein the mixture further comprises a third metal, wherein the first metal, second metal, and third metal are in stoichiometric proportions effective for forming the intermetallic compound; and
wherein the mixture is thermally treated to form a layer of the intermetallic compound comprising the first metal, the second metal, and the third metal.

21. A method of forming a vertical conductive line comprising:
providing an interconnection structure comprising:
at least one conductive contact, and
a layer of insulative material covering the at least one conductive contact;
exposing at least a portion of the conductive contact by forming an opening in the layer of insulative material;
depositing at least one layer comprising a first metal in at least a portion of the opening;
depositing at least one layer comprising a second metal on at least a portion of the layer of first metal; and
thermally treating the layer comprising the first metal and the layer comprising the second metal to form a layer of intermetallic compound comprising the first metal and the second metal.

22. The method of claim 21 further comprising depositing at least one layer comprising a third metal on at least a portion of the layer of the second metal, and wherein the layer comprising the first metal, the layer comprising the second metal, and the layer comprising the third metal are thermally treated to form a layer of intermetallic compound comprising the first metal, the second metal, and the third metal.

23. A method of forming a vertical conductive line comprising:
providing an interconnection structure comprising:
at least one conductive contact, and
a layer of insulative material covering the at least one conductive contact;
exposing at least a portion of the conductive contact by forming an opening in the layer of insulative material;
depositing a mixture comprising at least a first metal and a second metal in at least a portion of the opening, wherein the mixture comprises the first metal and the second metal in stoichiometric proportions effective for forming an intermetallic compound; and
thermally treating the mixture to form a layer of the intermetallic compound comprising the first metal and the second metal.

24. The method of claim 23 wherein the mixture further comprises a third metal, wherein the first metal, second metal, and third metal are in stoichiometric proportions effective for forming the intermetallic compound; and
wherein the mixture is thermally treated to form a layer of the intermetallic compound comprising the first metal, the second metal, and the third metal.
